(19) United States
(12) Patent Application Publication
(10) Pub. No.: US 2008/0089534 A1
(43) Pub. Date: Apr. 17, 2008

(54) Video playing apparatus and method of controlling volume in video playing apparatus

(75) Inventor: Bong-hwan Park, Hwaseong-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD., Suwon-si (KR)

(21) Appl. No.: 11/785,343

(22) Filed: Apr. 17, 2007

(30) Foreign Application Priority Data
Oct. 12, 2006 (KR) 10-2006-0099382

(51) Int. Cl. H03G 3/00; H04Q 1/00

(52) U.S. Cl. 381/105; 340/825.24; 700/94

(57) ABSTRACT

A video playing apparatus and a method of adjusting a sound volume of the video playing apparatus are provided. The video playing apparatus can adjust the volume if a predetermined key is input continuously.

### CROSS-REFERENCE TO RELATED APPLICATIONS

This application claims priority under 35 U.S.C. §119 from Korean Patent Application No. 10-2006-0099382, filed on Oct. 12, 2006 in the Korean Intellectual Property Office, the disclosure of which is incorporated herein by reference in its entirety.

### BACKGROUND OF THE INVENTION

1. Field of the Invention

Apparatuses and methods consistent with the present invention relate to controlling a sound volume of video being played, and more particularly, to controlling a sound volume of video being played according to whether a predetermined key is successively input.

2. Description of the Related Art

A television (TV) receives a broadcast from a broadcast station, separates the received broadcast into video and audio signals, and displays the video signal through a screen while outputting audio signal through a speaker.

A TV is generally provided with an audio mute function, which blocks the audio signal from outputting such that the video signal is displayed without sound.

The audio mute function may be used when it is necessary to turn down the volume of the TV immediately. A user can completely block the output of the audio signal using a mute key, without having to repeatedly press a volume adjusting key and gradually decreasing the volume.

When the audio is being played, the output of the audio signal through the speaker can be blocked by pressing the mute key. Generally, the volume of the sound is retained when the audio output is blocked.

Therefore, the audio output through the speaker is resumed at the same volume as before the mute mode, when the mute key is re-pressed.

The mute mode may be released automatically, in response to a volume adjusting key, and in this situation, the audio is at the volume set before the mute mode. In other words, a user cannot adjust the volume of audio sound in the mute mode.

Accordingly, the user experiences inconvenience. Because the user is unable to adjust the volume of the audio in the mute mode, the audio may be played too loud when the mute mode is released in response to the volume adjusting key or the mute key.

Furthermore, because the volume of the TV is retained and the TV may be too loud when the user turns on the TV, people around the TV, including the user, experience inconvenience until the user finally turns down the volume.

### SUMMARY OF THE INVENTION

Exemplary embodiments of the present invention overcome the above disadvantages and other disadvantages not described above. Also, the present invention is not required to overcome the disadvantages described above, and an exemplary embodiment of the present invention may not overcome any of the problems described above.

The present invention provides a video playing apparatus which adjusts a sound volume in response to a series of inputs of a predetermined key, and a method for adjusting the sound volume of the video playing apparatus.

The present invention also provides a video playing apparatus which adjusts a sound volume in response to a series of inputs of a predetermined key, in a mute mode, or in a standby mode such as a power-off mode, and a method for adjusting the sound volume of the video playing apparatus.

According to an exemplary embodiment of the present invention, a method of adjusting a sound volume of a video playing apparatus which outputs a video and an audio may include receiving a signal corresponding to a predetermined key, determining whether the signal is being received continuously for a predetermined period of time, and adjusting a current sound volume to a predetermined level, on determining that the signal is being received continuously for the predetermined period of time.

The method may further include determining whether the audio is being output, on determining that the signal is not being received continuously for the predetermined period of time, and determining whether to output audio according to the result of determination.

The determining whether to continue audio output may include blocking the audio output and retaining the current volume, on determining that the audio is being output, and outputting the audio according to the latest sound volume, on determining that the audio is not being output.

The adjusting the current sound volume to the predetermined level may include setting the predetermined sound volume as the latest volume.

The adjusting the current sound volume to the predetermined level may include displaying a message which indicates that the current sound volume is adjusted to a predetermined level.

The adjusting the current sound volume to the predetermined level may include displaying the predetermined level as the current sound volume on a user interface screen which displays the sound volume.

The adjusting the current sound volume to the predetermined level may be performed even when the video playing apparatus is in power-off state.

According to another exemplary embodiment of the present invention, a video playing apparatus which outputs a video and an audio, may include a key signal receiving unit which receives a signal corresponding to a predetermined key, a control unit which determines whether the signal is being received continuously for a predetermined period of time, and on determining that the signal is being received continuously for the predetermined period of time, adjusts a current sound volume to a predetermined level, and an audio output unit which outputs audio corresponding to the current sound volume.

The control unit may determine whether the audio is being output, on determining that the signal is not being received continuously for the predetermined period of time, and determine whether or not to output audio according to the result of determination.

The control unit, on determining that the audio is being output, may control such that the audio output is blocked and the current sound volume is retained, and on determining that the audio is not being output, control such that the audio is output at the latest sound volume.

The predetermined key may be a mute key.

The predetermined sound volume may be no sound.

The predetermined period of time may be one second.

A memory may be further provided, and the control unit may control such that the predetermined sound volume is set in the memory as the latest sound volume.

A display unit may be further provided, and the control unit may control the display unit to display a message which indicates that the current sound volume is adjusted to a predetermined level. Alternatively, the control unit may control the display unit to display the predetermined level as the current sound volume on a user interface screen which displays the sound volume.

The control unit may adjust the sound volume even when the video playing apparatus is in power-off state.

### BRIEF DESCRIPTION OF THE DRAWINGS

The above and/or other aspects of the present invention will be more apparent by describing certain exemplary embodiments of the present invention with reference to the accompanying drawings, in which:

FIG. 1 is a control block diagram of a video playing apparatus according to an exemplary embodiment of the present invention;

FIG. 2 illustrates an On-Screen Display (OSD) screen according to an exemplary embodiment of the present invention;

FIG. 3 illustrates an OSD screen according to another exemplary embodiment of the present invention;

FIG. 4 is a flowchart illustrating a method of adjusting a sound volume according to an exemplary embodiment of the present invention; and

FIG. 5 is a flowchart illustrating a method of adjusting a sound volume according to another exemplary embodiment of the present invention.

### DETAILED DESCRIPTION OF THE EXEMPLARY EMBODIMENTS

Certain exemplary embodiments of the present invention will now be described in greater detail with reference to the accompanying drawings.

In the following description, same drawing reference numerals are used for the same elements even in different drawings. The matters defined in the description, such as a detailed construction and elements, are provided to assist in a comprehensive understanding of the invention. Thus, it is apparent that the present invention can be carried out without those specifically defined matters. Also, well-known functions or constructions are not described in detail since they would obscure the invention with unnecessary detail.

In one exemplary embodiment, a video playing apparatus 1 may be implemented as a digital TV.

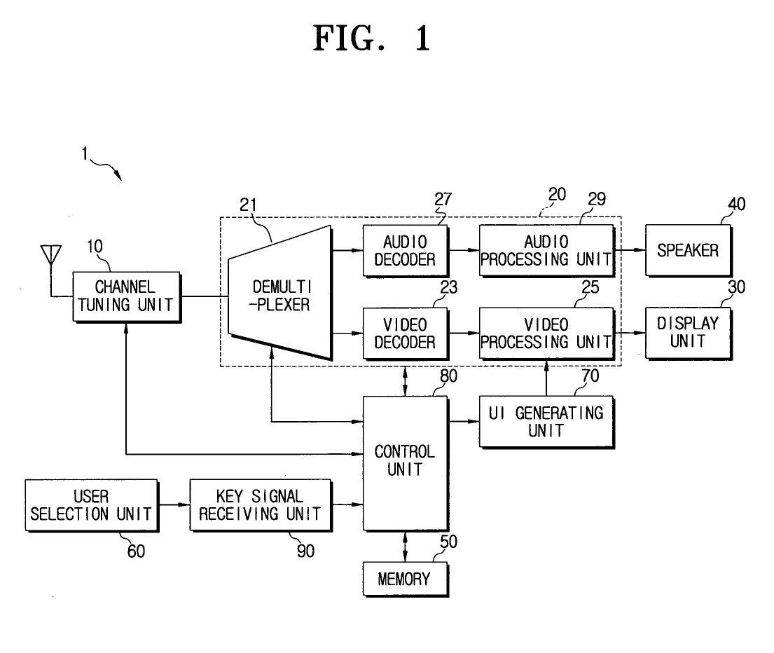

FIG. 1 is a control block diagram of a digital TV 1 as the video playing apparatus according to an exemplary embodiment of the present invention. The digital TV 1 may include a channel tuning unit 10, a signal processing unit 20, a display unit 30, a speaker 40, a memory 50, a user selection unit 60, a UI generating unit 70, a control unit 80, and a key signal receiving unit 90.

The channel tuning unit 10 may include a tuner which tunes to a broadcast being received over the antenna, and a demodulator which conducts processing such as demodulation and error correction of the tuned broadcast and outputs the broadcast in the form of a transport stream (TS). The channel tuning unit 10 may tune to the broadcast at a frequency band which corresponds to a control signal of the control unit 80, which will be explained in greater detail below.

The signal processing unit 20 may include a demultiplexer 21, a video decoder 23, a video processor 25, an audio decoder 27, and an audio processor 29.

The broadcast is demodulated at the channel tuning unit 10 and separated into a video signal, an audio signal, and additional data defined by the program and service information protocol (PSIP) at the demultiplexer 21, and output in the form of a bit stream.

The video signal being separated at the demultiplexer 21 is decoded at the video decoder 23, and converted at the video processor 25 to conform to the output specifications of the display unit 30 such as vertical frequency, resolution, aspect ratio, and the like. The video processor 25 may include a scaler.

The display unit 30 is adaptable to various display modules, including Digital Lighting Processing (DLP), Liquid Crystal Display (LCD), and Plasma Display Panel (PDP).

The audio signal being separated at the demultiplexer 21 is decoded at the audio decoder 27, and volume of the sound is adjusted at the audio processor 29, such that the adjusted audio signal is output through the speaker 40.

The additional data under PSIP being separated at the demultiplexer 21 may include EPG data, the guide information of the broadcast programs.

The user selection unit 60 may include a remote controller having a function of sound volume adjustment, and the remote controller may have a mute key and a key signal generator which generates a key signal in response to a manipulation on the key. In alternate embodiments, the user selecting unit 60 may include a mouse, a keyboard, or may be incorporated into a panel on the TV.

The key signal receiving unit 90 may receive a key signal being output from the user selecting unit 60 and transmit the received key signal to the control unit 80.

The digital TV 1 according to an aspect of the exemplary embodiment of the present invention may additionally include the UI generating unit 70. The UI generating unit 70 operates to generate an OSD including a message which notifies that the current volume has been adjusted to a predetermined level. The UI generating unit 70 may be implemented by use of an OSD generating integrated circuit (IC). The OSD being generated at the UI generating unit 70 may be processed at the video processing unit 25 and displayed at the display unit 30. The OSD being generated at the UI generating unit 70 may include an OSD which notifies the specific level of volume of the digital TV 1.

The control unit 80, upon receiving a signal corresponding to a mute key via the user selecting unit 60, controls the respective components to perform designated functions. The control unit 80 may be implemented as a micro processor, a Central Processing Unit (CPU), or the like.

More specifically, in response to a signal corresponding to the mute key being received at the key signal receiving unit 90 via the user selection unit 60, the control unit 80 determines whether the signal is being received more than a predetermined period of time, i.e., one second.

If it is determined that the mute key has been pressed for more than one second, that is, if the mute key is determined to have been continuously input more than one second, the control unit 80 may cause the current volume to be adjusted to a predetermined volume, such as, 0 (i.e., no sound). The control unit 80 may control the audio processing unit 29 in accordance with the adjusted volume such that the audio is output through an audio output unit such as the speaker 40 at the adjusted volume. The control unit 80 may control the audio processing unit 90 so that the audio is blocked from being output through the speaker 40.

If the mute key is not continuously pressed, the control unit 80 performs the ordinary operation of the mute key.

Accordingly, the control unit determines whether it is in mute mode. If it is determined that it is not in the mute mode and that the audio is currently being output, the control unit enters into the mute mode. According to the entry into the mute mode, the control unit 80 controls the audio output so that it is blocked while the current volume is retained.

If the mute key is pressed and it is the mute mode, that is, where the audio is not being output, the control unit 80 causes the mute mode to be released. That is, the control unit 80 may cause the audio to be output at the latest volume.

The memory 50 always stores the latest volume. Accordingly, if the control unit 80 causes the current volume to be adjusted to 0, the memory 50 stores 0 as the latest volume.

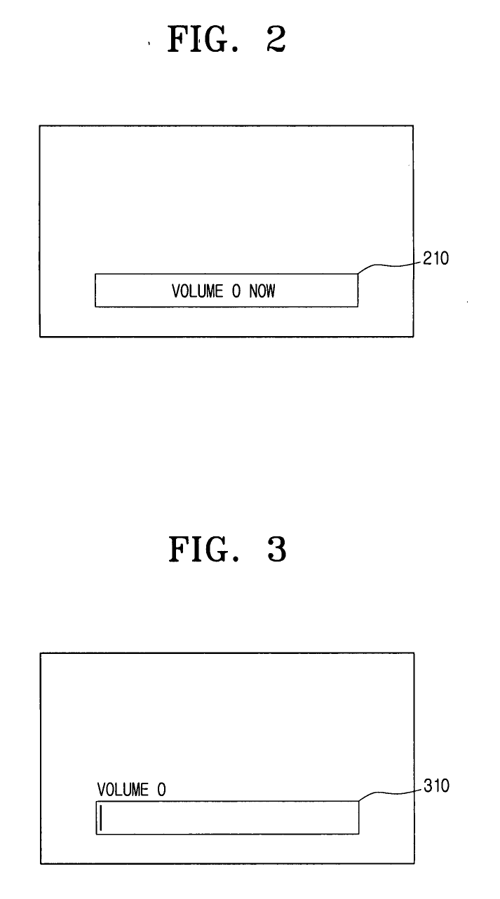

FIG. 2 illustrates an example where the current volume has been adjusted to 0 by the control unit 80, and the control unit 80 controls the display unit 30 so that it indicates a message “VOLUME 0 NOW”, which means that the current volume has been adjusted to 0.

FIG. 3 illustrates an alternative example where the control unit 80 controls the display unit 30 to indicate 0 through a user interface screen.

The video playing apparatus 1 according to an exemplary embodiment of the present invention may receive a signal of a predetermined key and accordingly adjust the volume, even when it is turned off.

Because the volume of the TV can be adjusted to 0 by pressing a mute key for more than one second when the TV (i.e., video playing apparatus 1) is in an off state, user discomfort due to an unexpectedly loud sound of the TV when the user turns the TV on, can be avoided.

In another exemplary implementation, the video playing apparatus 1 may perform the same volume adjustment that is provided when the video playing apparatus 1 is activated in response to a mute key pressed more than one second as a part of the initialization process of the video playing apparatus 1. In this way, the user's inconvenience can be avoided because the user does not have to turn on the video playing apparatus 1 by pressing a power key, and then press the mute key more than one second to lower the volume.

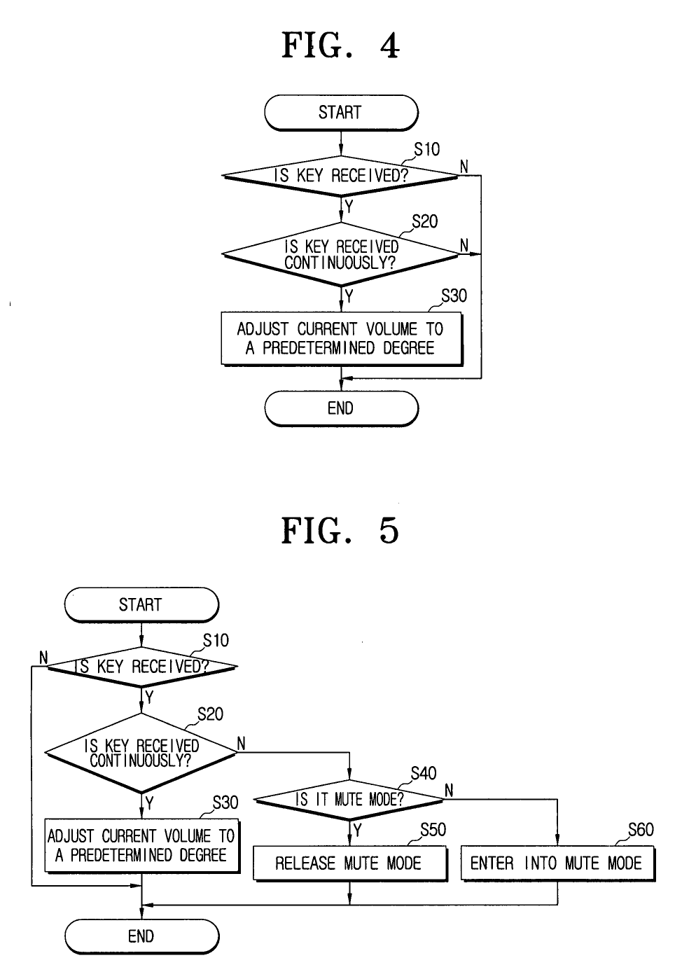

The volume adjusting method of a video playing apparatus according to an exemplary embodiment of the present invention will be explained below with reference to FIG. 4.

First, it is determined whether a signal corresponding to a predetermined key is received (S10). The predetermined key may comprise a mute key. Upon determining that the signal corresponding to predetermined key is received at operation S10, it is determined whether the signal is continuously received for more than a predetermined period of time (S20). In other words, it is determined whether the predetermined key is pressed continuously. The predetermined period of time may desirably be one second.

If it is determined at operation S20 that the signal is continuously received for more than the predetermined period of time, that is, if it is determined that the key is being pressed continuously, the current volume, is adjusted to a predetermined level (S30). The predetermined level may desirably be 0 (i.e., no sound). As a result, audio output through the speaker 40 may be blocked.

The predetermined volume level 0 may be stored as the latest volume.

As shown in FIG. 2, a message may be displayed to indicate that the volume has been adjusted to a predetermined level.

Alternatively, the currently volume may be displayed through the user interface screen, as shown in FIG. 3.

A method of adjusting the volume of the video playing apparatus according to another exemplary embodiment of the present invention will now be explained below with reference to FIG. 5.

The volume adjusting method may include operations S10 to S30 of the above exemplary embodiment, and operations S10 to S30 will not be explained below for the sake of brevity. At operation S20, if it is determined that the signal is not received continuously, that is, if it is determined that the key is input briefly, it is determined whether it is currently a mute mode (S40).

Upon determining it to be the mute mode at operation S40, that is, upon determining that no audio is being output currently, the mute mode is released (S50). Audio can be output at the latest volume when the mute mode is released. Additionally, the mute OSD is not displayed any more, when the mute mode is released.

Upon determining that it is not the mute mode and that audio is being output currently at operation S40, the video playing apparatus enters into the mute mode (S60). Upon entering into the mute mode, audio output through the speaker 40 is blocked, but the current volume is retained. Additionally, a mute OSD may be displayed on the display unit 30 to indicate that it is mute mode.

With the volume adjusting method according to the exemplary embodiment of the present invention, a signal corresponding to the predetermined key may be received and the volume can be adjusted to a predetermined level, even when the video playing apparatus is in the off state.

More specifically, the volume can be adjusted to 0 by pressing the mute key for more than one second, when the TV is in the off state. Because the volume of the TV can be adjusted even when the TV is in the off state, user discomfort due to unexpectedly loud sound of the TV when the user turns it on, can be avoided.

Although the digital TV was explained above according to one exemplary embodiment of the present invention, one will understand that the present invention can be incorporated into other video playing apparatuses which receive signal corresponding to a mute key and adjust the volume. For example, the present invention may apply to a set top box.

Furthermore, although the digital TV was explained above as receiving a broadcast according to one exemplary embodiment of the present invention, one will understand that the digital TV may receive a signal from an external device and output the received signal.

Furthermore, although the video playing apparatus was explained above as being adjusted to volume 0 in the exemplary embodiment of the present invention, one will understand that the level of adjustment may vary in a range that is audible and not unpleasantly loud for the viewers.

Furthermore, although the predetermined key was explained as being pressed more than 1 second in the exemplary embodiment of the present invention, one will understand that the period of time may vary to, for example, three seconds, if viewers feel it more convenient.

As explained above, according to the exemplary embodiments of the present invention, a volume of a video playing apparatus can be adjusted in a mute mode by pressing a predetermined key continuously.

Additionally, the volume of the video playing apparatus can be adjusted to a desirable level before the mute mode is released so that user can turn down the volume if the video playing apparatus was played at a loud volume before entering into the mute mode.

Furthermore, the volume of the video playing apparatus can be adjusted in a standby mode, that is, in power-off state, so that user discomfort due to unexpected loudness of the apparatus when the apparatus is turned on, can be avoided.

The foregoing exemplary embodiments and advantages are merely exemplary and are not to be construed as limiting the present invention. The present teaching can be readily applied to other types of apparatuses. Also, the description of the exemplary embodiments of the present invention is intended to be illustrative, and not to limit the scope of the claims, and many alternatives, modifications, and variations will be apparent to those skilled in the art.

What is claimed is:

1. A method of adjusting a sound volume of a video playing apparatus which outputs a video and an audio, the method comprising:
receiving a signal corresponding to a key;
determining whether the signal is received continuously for a period of time; and
adjusting a current sound volume to a level if it is determined that the signal is received continuously for the period of time.

2. The method of claim 1, further comprising:
determining whether the audio is being output if it is determined that the signal is not received continuously for the period of time; and
determining whether to output the audio according to a result of the determination whether the audio is being output.

3. The method of claim 2, wherein the determining whether to continue the audio output comprises:
blocking the audio output and retaining the current volume if it is determined that the audio is being output; and
outputting the audio according to a latest sound volume if it is determined that the audio is not being output.

4. The method of claim 1, wherein the key comprises a mute key.

5. The method of claim 1, wherein the sound volume is no sound.

6. The method of claim 1, wherein the period of time comprises 1 second.

7. The method of claim 1, wherein the adjusting the current sound volume to the level comprises setting the sound volume as the latest volume.

8. The method of claim 1, wherein the adjusting the current sound volume to the level comprises displaying a message which indicates that the current sound volume is adjusted to a level.

9. The method of claim 1, wherein the adjusting the current sound volume to the level comprises displaying the level as the current sound volume on a user interface screen which displays sound volume.

10. The method of claim 1, wherein the adjusting the current sound volume to the level is performed even if the video playing apparatus is in a power-off state.

11. A video playing apparatus which outputs a video and an audio, the video playing apparatus comprising:
a key signal receiving unit which receives a signal corresponding to a key;
a control unit which determines whether the signal is received continuously for a period of time, and if it is determined that the signal is received continuously for the period of time, adjusts a current sound volume to a certain level; and
an audio output unit which outputs audio corresponding to the current sound volume.

12. The video playing apparatus of claim 11, wherein the control unit determines whether the audio is being output if it is determined that the signal is not received continuously for the period of time, and determines whether to output the audio according to the result of the determination whether the audio is being output.

13. The video playing apparatus of claim 12, wherein the control unit, if it determined that the audio is being output, blocks the audio output and retains the current sound volume, and if it is determined that the audio is not being output, outputs the audio at a latest sound volume.

14. The video playing apparatus of claim 11, wherein the key comprises a mute key.

15. The video playing apparatus of claim 11, wherein the certain level is no sound.

16. The video playing apparatus of claim 11, wherein the period of time is one second.

17. The video playing apparatus of claim 11, further comprising a memory, wherein the control unit sets the sound volume in the memory as a latest sound volume.

18. The video playing apparatus of claim 11, further comprising a display unit, wherein the control unit controls the display unit such that the display unit displays a message which indicates that the current sound volume is adjusted to the certain level.

19. The video playing apparatus of claim 11, further comprising a display unit, wherein the control unit controls the display unit such that the display unit displays the level as the current sound volume on a user interface screen.

20. The video playing apparatus of claim 11, wherein the control unit adjusts the sound volume even if the video playing apparatus is in a power-off state.
